(19) United States
(12) Patent Application Publication
(10) Pub. No.: US 2006/0175013 A1
(43) Pub. Date: Aug. 10, 2006

(54) Specimen surface treatment system

(76) Inventor: Michael Cox, Apache Junction, AZ (US)

Correspondence Address: DINSMORE & SHOHL LLP;One Dayton Centre, Suite 1300, One South Main Street, Dayton, OH, 45402-2023, US

(21) Appl. No.: 11/055,024

(22) Filed: Feb. 10, 2005

(51) Int. Cl. C23F 1/00; H01L 21/306; B08B 6/00

(52) U.S. Cl. 156/345.43; 216/67; 134/1.1; 156/345.29

(57) ABSTRACT

In accordance with one embodiment of the present invention, a specimen surface treatment system is provided comprising a vacuum chamber, a plasma chamber, a specimen holder port, and a specimen shield. The plasma chamber comprises an RF antenna positioned within the vacuum chamber so as to give rise to a capacitively coupled glow discharge plasma in a process gas contained within the vacuum chamber. The specimen shield is positioned within the vacuum chamber so as to define a preferred grounding path between the RF antenna and the specimen shield for ions generated in the plasma. The grounding path is preferred relative to a grounding path defined between the RF antenna and the specimen position. Additional embodiments are disclosed.

### CROSS REFERENCE TO RELATED APPLICATIONS

The present application is related to commonly assigned U.S. patent application Ser. No. ______, (GAT 0103 PA) for CONTROL OF PROCESS GASES IN SPECIMEN SURFACE TREATMENT SYSTEM, filed concurrently herewith.

### BACKGROUND OF THE INVENTION

The present invention relates to a scheme for plasma treatment of a specimen and, more particularly, to a scheme for plasma assisted removal of contaminants from the surface of a specimen. The concepts of the present invention may find specific application in removing contaminants such as hydrocarbons, oxides, photoresists, and other metallic and organic contaminants, from semiconductor specimens. The concepts of the present invention may find further application in the preparation of specimens for examination in a microscope, such as a scanning electron microscope, a transmission electron microscope, an Auger electron microscope, etc.

### BRIEF SUMMARY OF THE INVENTION

According to the present invention, an improved specimen surface treatment system employing a glow discharge plasma mechanism is provided. Various methods are also provided for the removal of contaminants from a surface of a specimen.

In accordance with one embodiment of the present invention, a specimen surface treatment system is provided comprising a vacuum chamber, a plasma chamber, a specimen holder port, and a specimen shield. The plasma chamber comprises an RF antenna positioned within the vacuum chamber so as to give rise to a capacitively coupled glow discharge plasma in a process gas contained within the vacuum chamber. The specimen shield is positioned within the vacuum chamber so as to define a preferred grounding path between the RF antenna and the specimen shield for ions generated in the plasma. The grounding path is preferred relative to a grounding path defined between the RF antenna and the specimen position.

In accordance with another embodiment of the present invention, a specimen surface treatment system is provided comprising a vacuum chamber, a plasma chamber, and first and second specimen holder ports defined in the vacuum chamber. The first and second specimen positions defined by the first and second specimen holder ports lie in the same or substantially equivalent glow discharge plasma zones within the vacuum chamber.

In accordance with yet another embodiment of the present invention, a method of removing hydrocarbon contaminants from a surface of a specimen is provided. The method comprises (i) positioning the specimen within a vacuum chamber of a surface treatment system; (ii) generating a glow discharge plasma within the vacuum chamber; and (iii) removing the specimen from the vacuum chamber following contaminant removal by isolating at least a portion of the evacuation system from the vacuum chamber in a manner sufficient to hinder transfer of hydrocarbon contaminants from the evacuation system to the vacuum chamber as the vacuum chamber is vented to atmospheric pressure.

In accordance with yet another embodiment of the present invention, a method of removing contaminants from a surface of a specimen is provided. The method comprises: (i) positioning the specimen within a vacuum chamber of a surface treatment system; (ii) generating a glow discharge plasma within the vacuum chamber; and (iii) removing the specimen from the vacuum chamber following contaminant removal by introducing a gas into the vacuum chamber in a manner sufficient to hinder backstreaming of hydrocarbon contaminants from the evacuation system to the vacuum chamber as the vacuum chamber is vented to atmospheric pressure.

In accordance with yet another embodiment of the present invention, a method of removing hydrocarbon contaminants from a surface of a specimen is provided. The method comprises: (i) positioning a specimen within a vacuum chamber; (ii) maintaining the vacuum chamber below atmospheric pressure; (iii) introducing a process gas into the vacuum chamber, wherein the process gas comprises a mixture of H₂ and O₂; (iv) generating a plasma discharge comprising species of hydrogen and oxygen in said vacuum chamber.

In accordance with yet another embodiment of the present invention, a method of removing hydrocarbon contaminants from a surface of a specimen is provided where a plasma chamber comprising an RF antenna positioned within an enclosure under vacuum is operated so as to generate a capacitively coupled plasma discharge. The specimen is subject to exposure to species of hydrogen and oxygen accelerated by a potential generated at least in part by the RF antenna.

In accordance with yet another embodiment of the present invention, a method of removing hydrocarbon contaminants from a surface of a specimen is provided wherein a process gas and a hydrogen precursor are introduced into the vacuum chamber. The plasma chamber is operated so as to generate a plasma discharge in the vacuum chamber such that the specimen is subject to exposure to species of hydrogen generated from the hydrogen precursor.

In accordance with yet another embodiment of the present invention, a specimen surface treatment system is provided where the process gas supply comprises an electrolysis unit configured to introduce a mixture of H₂ and O₂ into the vacuum chamber.

Accordingly, it is an object of the present invention to provide for improved schemes for plasma treatment of a specimen. Other objects of the present invention will be apparent in light of the description of the invention embodied herein.

### BRIEF DESCRIPTION OF THE SEVERAL VIEWS OF THE DRAWINGS

The following detailed description of specific embodiments of the present invention can be best understood when read in conjunction with the following drawings, where like structure is indicated with like reference numerals and in which:

FIG. 1 is a plan view of a specimen surface treatment system according to one embodiment of the present invention;

FIG. 2 is a cross sectional view of a specimen surface treatment system according to the present invention, taken along line 2-2 of FIG. 1;

FIG. 3 is a cross sectional view of a specimen surface treatment system according to the present invention, taken along line 3-3 of FIG. 1; and

FIGS. 4-7 are schematic illustrations of a variety of evacuation system configurations for specimen surface treatment systems according to the present invention.

### DETAILED DESCRIPTION

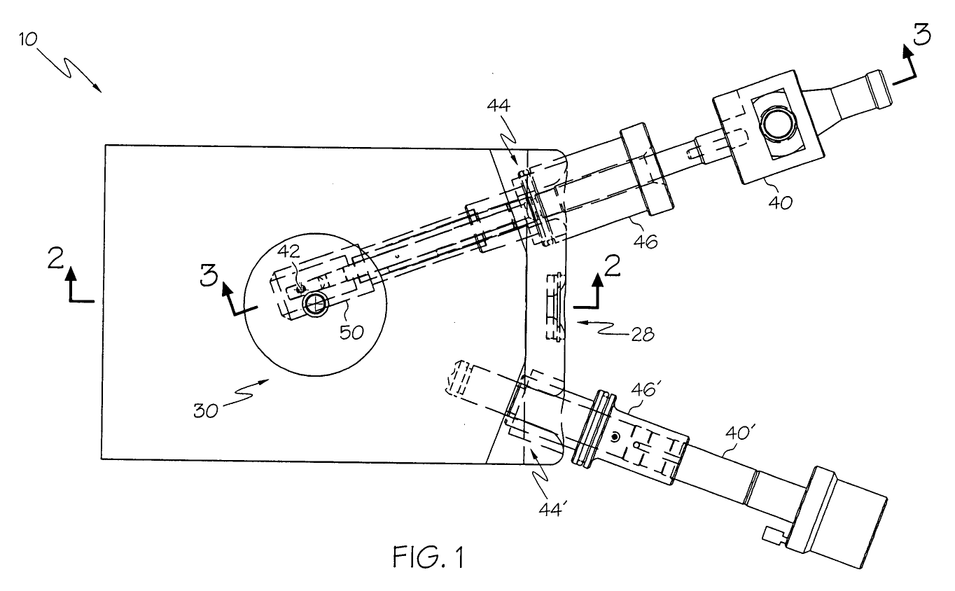

Referring initially to FIGS. 1-3, a specimen surface treatment system 10 according to the present invention is illustrated. The system comprises a vacuum chamber 20, a plasma chamber 30, a specimen holder 40 and associated specimen holder port 44, and a specimen shield 50. The Plasma chamber 30 comprises a radio frequency antenna 32 positioned within the vacuum chamber 20 so as to give rise to a capacitively coupled glow discharge plasma in a process gas contained within the vacuum chamber 20. The specimen holder 40 and port 44 are configured to define a specimen position 42 within the capacitively coupled glow discharge and to permit introduction of a specimen into the vacuum chamber 20. The specimen holder 40 and port 44 are also configured to permit subsequent removal of the specimen from the vacuum chamber 20. In the context of the treatment of specimens for electron microscopy, it is noted that the particular design of the specimen holder 40 will be dictated by the microscope with which it is associated. For example, the specimen holder 40 may be any one of a variety of specimen holders used in particular transmission or scanning electron microscopes.

An additional specimen holder 40′ and specimen holder port 44′ can also be provided to enable simultaneous or alternating treatment of different specimens. Preferably, the additional specimen holder 40′ and port 44′ will define a specimen position (not shown for clarity) that lies in the same or a substantially equivalent plasma discharge zone of the vacuum chamber 20. In this manner, treatment operations will not vary as operations alternate from one holder/port to the other. To accommodate specimen holders 40, 40′ of different designs, each port 44, 44′ can be provided with port adapters 46, 46′ designed to match different types of specimen holders. For the purposes of defining and describing the present invention, it is noted that substantially equivalent plasma discharge zones will be characterized by substantially the same plasma conditions with respect to the identity and physical properties of the particles within the equivalent regions.

The specimen shield 50 is positioned within the vacuum chamber 20 such that it defines a preferred grounding path P1 for ions generated in the plasma from the process gas. More specifically, the grounding path P1 defined between the RF antenna 32 and the specimen shield 50 is preferred relative to a grounding path P2 defined between the RF antenna 32 and the specimen position 42 defined by the specimen holder 40 and port 44. In this manner, potentially damaging plasma particles generated in the vicinity of the RF antenna 32 and having relatively high electric potential are more likely to directly impinge upon the shield 50 as opposed to a specimen held in the specimen position 42 because the path P1 is much more direct than the path P2. Lower potential plasma particles generated farther along the indirect path P2 are more likely to find their way to the specimen position 42.

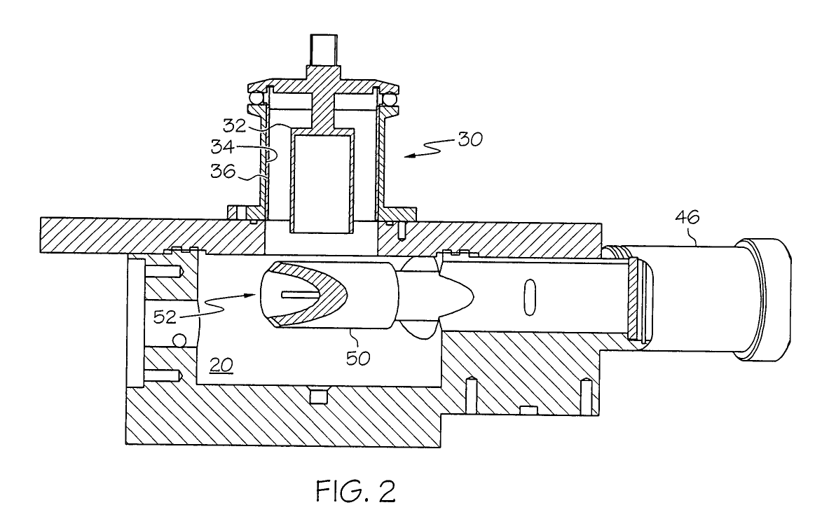

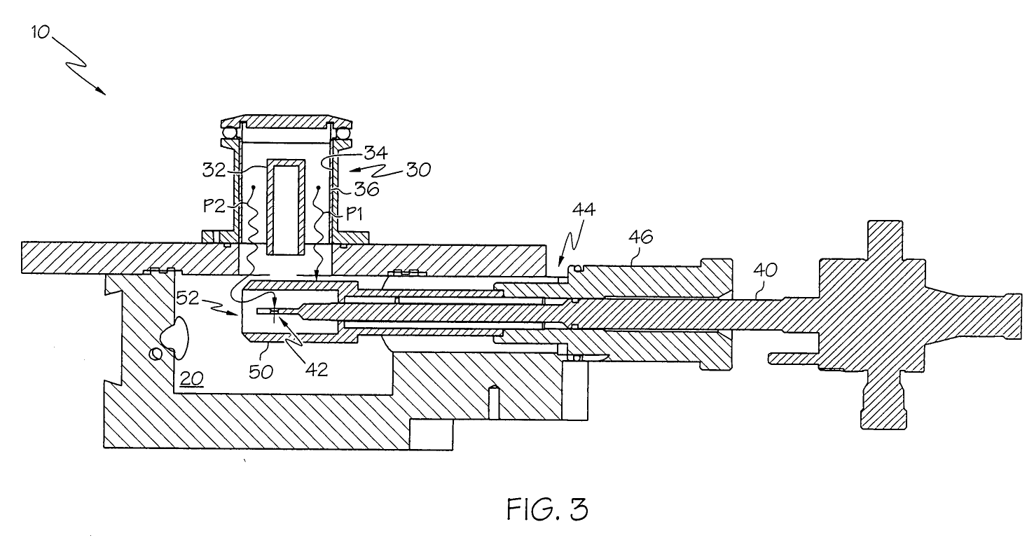

As is illustrated in FIGS. 2 and 3, the RF antenna 32, the specimen shield 50, and the specimen holder 40 may be positioned within the vacuum chamber 20 such that, at the very least, a substantial portion of the specimen shield 50 lies between the RF antenna 32 and the specimen holder 40. The shield 50 may be configured, for example, to obstruct substantially all lines of sight defined between the RF antenna 32 and the specimen position 42. In this manner, the distinction between the preferred grounding path P1 and the indirect grounding path P2 may be established clearly. Also illustrated in FIGS. 1-3 is additional process monitoring and control equipment in communication with the interior of the vacuum chamber 20, the details of which are beyond the scope of the present invention.

The RF antenna 32, the specimen shield 50, and the specimen holder 40 are positioned within the vacuum chamber 20 such that a plasma potential in a shielded region 52 between the shield 50 and the specimen holder 40 is less than about 30V above a floating potential of the specimen holder 40. For example, specific configurations of the present invention yield a plasma potential within the shielded region 52 of about 20V above the floating potential of the specimen holder 40. The plasma potential in the shielded region 52 is typically greater than 20V above the floating potential of the specimen shield 50 because the shield is typically closer to ground than the specimen.

It is contemplated that the shield 50, illustrated as a substantially hollow cylindrical shield in FIGS. 1-3, could take a variety of forms. For example, in many embodiments of the present invention, it will be sufficient to ensure that the RF antenna 32, the specimen shield 50, and the specimen holder 40 are positioned within the vacuum chamber such that at least a substantial portion of the specimen shield, whatever form it takes, lies between the RF antenna 32 and the specimen holder 40. It may sometimes be desirable to ensure that the shield 50 surrounds the specimen position 42. In which case it is likely to be advantageous to ensure that the specimen shield 50 defines a plasma port along the plasma path between the RF antenna 32 and the specimen holder 40.

In the case of the hollow cylindrical shield 50 of FIGS. 1-3, where the plasma path P2 between the RF antenna 32 and the specimen holder 40 is indirect and incorporates a change in direction approximating an angle of at least about 90 degrees, the plasma port is defined by the open end of the cylindrical shield 50. Further, it can be advantageous to ensure that the hollow cylindrical shield 50 is substantially closed about the periphery of the specimen holder 40 and does not contain any apertures along its circumference to further limit the ability of high energy ions to contact a specimen in the specimen holder 40.

Although a variety of RF antenna configurations are contemplated by the present invention, it is noted that the illustrated embodiment comprises a hollow cathode glow discharge antenna 32. Similarly, although a variety of RF antenna power supplies are contemplated by the present invention, it is noted that plasma chambers configured to operate between about 10 W and about 100 W are likely to be suitable.

In the RF antenna configurations illustrated in FIGS. 1-3, the plasma chamber 30 defines a portion of the vacuum chamber 20 and is formed, at least in part, by a conductive material. The RF antenna 32 is positioned within the plasma chamber 30 of the vacuum chamber 20. According to one embodiment of the present invention, a capacitive coating 36 is formed over a conductive portion 34 of the inner wall of the plasma chamber 30 to yield a capacitively coupled plasma discharge of enhanced effectiveness in hydrocarbon removal. For the purposes of defining and describing the present invention, it is noted that a capacitive coating comprises any continuous or discontinuous coating of material that functions to reduce substantially the DC conductivity of the interior surface of the conductive portion 34 of the plasma chamber 30.

The degree to which the DC conductivity of the interior surface of the plasma chamber 30 should be decreased will vary and will primarily depend upon the specific operational requirements of the particular cleaning or treatment process at hand. For example, and not by way of limitation, a capacitive coating 36 characterized by a capacitance that varied from about 2 picofarads to about 900 picofarads over the inner wall of the plasma chamber 30 was sufficient to yield enhanced hydrocarbon removal. Of course, it is also contemplated that various embodiments of the present invention will enjoy enhanced operation with capacitive coatings outside of the above-noted range. Still other embodiments of the present invention may not benefit from addition of the capacitive coating 36.

Although capacitive coatings according to the present invention may take a variety of forms, it is contemplated that a substantially non-conductive carbonaceous coating may be utilized within the scope of the present invention. By way of illustration and not limitation, additional candidates for suitable capacitive coatings include dielectric and electrolytic coatings, ceramic coatings, polymeric coatings, and organic or inorganic coatings.

In the illustrated embodiment, the conductive portion 34 and the RF antenna 32 define substantially concentric cylindrical cross sections and the capacitive coating 36 is distributed about the interior circumference of the conductive portion 34 of the plasma chamber 30. Of course, it is contemplated by the present invention that the coating 36 may be formed over substantially the entire interior surface of the Plasma chamber 30 or merely a portion of the interior surface. It is noted that, for the purposes of defining and describing the present invention, the term “over” contemplates formation of a coating in direct contact with an underlying material or in direct contact with an intervening layer formed on the underlying material. In contrast, the term “on” as utilized herein refers to direct formation of a coating on an underlying material.

Carbonaceous capacitive coatings 36 may be formed in any suitable manner and may comprise any of a variety of capacitive materials including, but not limited to amorphous, semi-amorphous, or crystalline carbon films, graphite coatings, diamond-like carbon coatings, carbon black coatings, glassy carbon films, carbon fiber or carbon nanotube coatings, or other graphites, hard carbons, or soft carbons, or mixtures including carbon and non-carbonaceous materials.

In accordance with one embodiment of the present invention, a carbonaceous capacitive coating 36 is formed by first increasing the roughness of the interior surface of the Plasma chamber 30 through direct mechanical abrasion, chemical roughening, or any other suitable surface roughening process. Following the roughening step, the interior surface is subject to a suitable plasma cleaning process. For example, it is contemplated that any of the hydrogen/oxygen based plasma cleaning processes described herein would be suitable. It is also contemplated that it may be desirable to run the plasma cleaning process at an RF power of about 50 W for an extended period of time, e.g., up to about 16 hours of plasma generation. The actual duration of the cleaning operation is introduced herein for the purposes of illustration only and may vary significantly from the duration disclosed herein.

Following roughening and plasma cleaning, a graphite antenna 32 is installed in the Plasma chamber 30. Plasma generation is initiated in a process gas of Ar, Xe, or another suitable plasma process gas, and is maintained at increased RF power, e.g., about 100 W. The plasma generation with the graphite antenna 32 is maintained for an amount of time sufficient to form a carbonaceous capacitive coating 36 of suitable thickness and uniformity over the conductive portion 34 of the Plasma chamber 30. It is anticipated that this stage of plasma generation should again be characterized by a significant duration, e.g., up to about 16 hours. It is also noted that the actual duration of this operation is introduced herein for the purposes of illustration only and may vary significantly from the duration disclosed herein.

As is noted above, the Plasma chamber 30 is operated to create capacitively coupled glow discharge plasma in a process gas contained within the vacuum chamber 20. To this end, the treatment system 10 further comprises a process gas supply 60 (illustrated schematically) that is configured to introduce a process gas into the vacuum chamber 20. Although the present invention contemplates utilization of a variety of process gases, according to one embodiment of the present invention, a process gas mixture of H₂ and O₂ is introduced into the vacuum chamber 20. The resulting plasma contains species of hydrogen and oxygen, e.g., hydrogen radicals, oxygen radicals, hydroxyl radicals, H₂ ions, and O₂ ions. These components of the plasma act to remove hydrocarbons from a surface of the specimen by causing the formation of CO, CO₂, and carbon chains at the surface. It may be preferable to ensure that the vacuum chamber is substantially free of nitrogen, argon, and other potentially harmful process gases to avoid specimen damage from sputtering by high energy ions of these gases. It is contemplated however that sufficient cleaning may also be achieved by merely adding a hydrogen precursor to another process gas suitable for creating capacitively coupled glow discharge plasma. For example, it is contemplated that suitable hydrogen precursors include, but are not limited to, hydrogen, a mixture of hydrogen and oxygen, and H₂O in a solid, liquid or vapor form. For example, a hydrogen precursor could be supplied with argon, nitrogen, air, oxygen, mixtures thereof, or other gas mixtures are suitable for plasma generation.

In certain embodiments of the present invention, the process gas in the vacuum chamber comprises a mixture that is predominantly O₂. More specifically, the process gas in the vacuum chamber may comprise between about 50% partial pressure O₂ and about 90% partial pressure O₂ and between about 10% partial pressure H₂ and about 50% partial pressure H₂. In one specific embodiment of the present invention, the process gas in the vacuum chamber comprises about two times as much O₂ as H₂, by pressure. While it is contemplated that a variety of process gas supplies may be utilized with the present invention, it is noted that the process gas supply 60 may comprise an electrolysis unit configured to generate hydrogen through electrolysis of water. Further, the surface treatment system 10 may be configured to recycle H₂O generated within the vacuum chamber to the electrolysis unit. In this manner, those practicing the present invention may relieve themselves of the various constraints attendant to the storage and handling of pressurized H₂ and O₂ and avail themselves of the convenience of a specimen surface treatment system of enhanced portability and versatility.

Although any suitable conventional or yet to be developed reaction cell configuration would be applicable to the present invention, for the purposes of illustration, it is noted that one class of suitable electrolysis cells are provided with a stack of membrane electrode assemblies (MEA), each including a proton exchange membrane (PEM) interposed between a hydrogen electrode and an oxygen electrode. Typically, an electric potential of about 1.8 volts is applied across the electrodes. The PEM separates water supplied to the positive oxygen electrode into hydrogen ions and oxygen. The positive hydrogen ions pass through the PEM to the negative hydrogen electrode. Electrons from the power source react with the hydrogen ions to form hydrogen gas. The gas is then stored in a tank for later use. Oxygen produced in the reaction at the oxygen electrode can also be stored for use.

In operation, hydrocarbon contaminants can be removed from a surface of a specimen held in the vacuum chamber by maintaining the vacuum chamber at a suitable pressure and introducing into the vacuum chamber 20 a process gas comprising a mixture of H₂ and O₂. A capacitively coupled plasma discharge is generated in the vacuum chamber 20 such that the specimen is subject to exposure to species of hydrogen and oxygen from the plasma discharge.

The specimen position 42 is defined within the chamber 20 such that a difference in electrical potential between the capacitively coupled plasma discharge and the specimen is sufficient to subject the specimen to exposure to the species of hydrogen and oxygen from the plasma. Further, the difference in electrical potential is sufficiently small to ensure that the exposure to the species of hydrogen and oxygen does not lead to substantial degradation of the specimen, beyond removal of the hydrocarbon contaminants. According to one embodiment of the present invention, the plasma chamber 30 is operated such that the difference in electrical potential between the capacitively coupled plasma discharge and the specimen, in relative close proximity to the specimen, is less than about 30V. For the purposes of defining and describing the present invention, it is noted that a region of the plasma discharge in “relative close proximity” to the specimen should be understood to include areas in the general vicinity of the specimen position 42 and to exclude areas in the chamber 20 that are relatively remote from the specimen position 42. For example, an area generally adjacent to one of the end walls of the chamber 20 would not be considered to be in relative close proximity to the specimen position 42 but areas near the specimen shield 50 would generally be considered to be in relative close proximity to the specimen position 42.

Although many embodiments of the present invention are illustrated in the context of a capacitively coupled plasma discharge, it is noted that many of the treatment schemes disclosed herein will have utility in the context of plasma generated in other ways. This is particularly true for the hydrocarbon removal utilizing species of hydrogen, oxygen, and hydroxyl, and for the evacuation and process gas flow configurations described herein. For example, the plasma discharge may comprise an inductively coupled plasma.

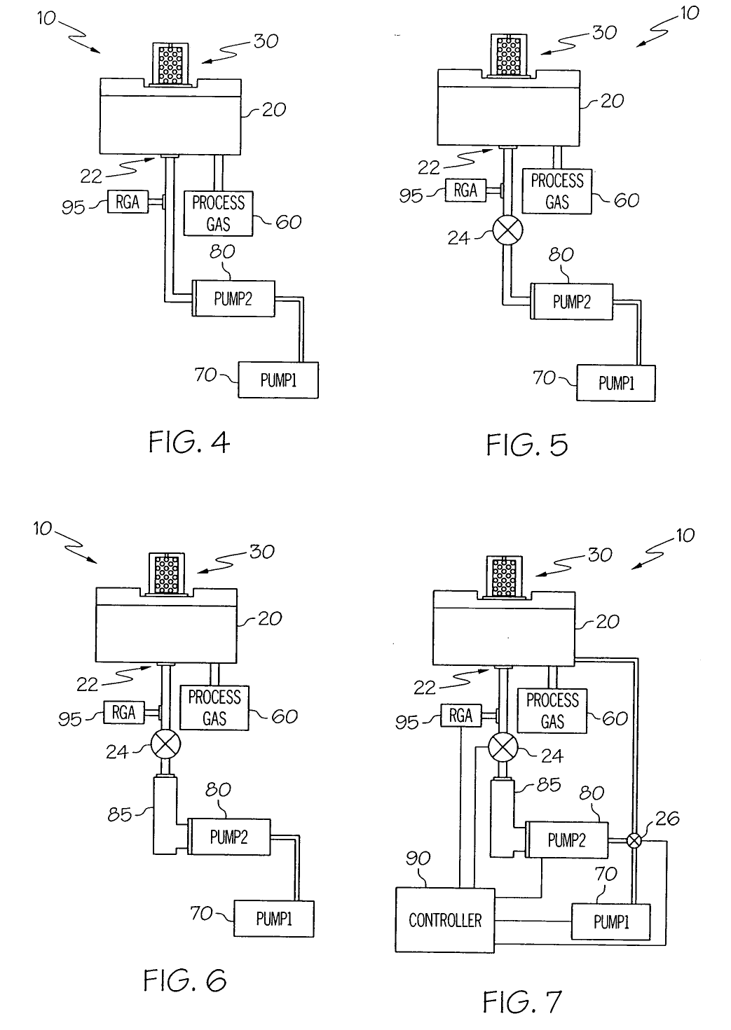

The vacuum chamber 20 is preferably maintained at less than about 600 mTorr (80 Pa) or, more specifically, between about 300 mTorr (40 Pa) and about 600 mTorr (80 Pa). To this end, referring to FIGS. 4-7, the evacuation system of the present invention may comprise first and second pumps 70, 80 configured to provide a suitable vacuum level in the vacuum chamber 20 for the generation and maintenance of the glow discharge plasma, e.g., about 420 mTorr (55 Pa) with the process gas flowing. The first pump 70 is typically configured to evacuate the vacuum chamber 20 from atmospheric pressure to a reduced pressure and the second pump 80 is typically configured to evacuate the vacuum chamber 20 from the reduced pressure to a further reduced pressure.

For example, the first pump 70 may comprise a diaphragm pump and the second pump 80 may comprise a turbomolecular drag pump backed by the diaphragm pump. Typical turbo pumps require a backing pump or pre-pumped outlet. Thus, the diaphragm pump is connected to the turbo pump by a suitable vacuum line to reduce the foreline or outlet pressure of turbo pump to a suitable value. Of course, a variety of suitable pumping configurations are contemplated by the present invention.

Referring more specifically to the evacuation system configurations of FIGS. 4-7, the evacuation systems of the illustrated embodiments are coupled to the vacuum chamber 20 via an evacuation port 22 provided in the chamber 20. As the system transitions from the active cleaning cycle to an idle state, the vacuum chamber returns to atmospheric pressure to permit removal of the treated specimen. The present inventors have recognized that the risk of contamination increases as the specimen remains in the chamber 20 during shutdown. For example, one source of contamination is the hydrocarbon-based lubricants used in the pumping components of the evacuation system. These contaminants may simply backstream into the vacuum chamber 20 along the vacuum line running from the chamber 20 to the pumping components. To remedy this potential source of contamination, the vacuum line extending from the evacuation port 20 may comprise an inline valve 24 configured to isolate the evacuation system from the vacuum chamber 20 when the inline valve 24 is in a closed state, as is illustrated in FIGS. 5-7. The inline valve 24 can be closed prior to, during, or shortly after system shut down, to keep contaminants such as oil from the pumping components of the evacuation system from reaching the vacuum chamber 20 and contaminating a treated specimen. By promptly closing the valve 24, a user can access and remove the specimen from the vacuum chamber in a fraction of the time that would normally be required because it is no longer necessary to wait for the pumping components to shut down completely.

Backstreaming of hydrocarbon contaminants may also be prevented by introducing an inert gas into the vacuum chamber 20 while venting the chamber to atmospheric pressure and removing the specimen. It is also contemplated that backstreaming may be prevented by continuing to introduce the process gas into the chamber during venting and removal. As will be appreciated by those practicing the present invention, the rate at which the process gases should be introduced into the vacuum chamber according to this aspect of the present invention may vary from the rate at which the process gases are introduced into the chamber during plasma generation.

As is illustrated in FIGS. 6 and 7, the evacuation system may further comprise a vacuum ballast chamber 85 positioned between the inline valve 24 and the second pump 80. The vacuum ballast chamber 85 allows for more effective transition between a cleaning cycle and a system idle state because it is not necessary to start-up and shut-down the second pump 80 during the transition—the pump 80 can remain operational at full speed. In the idle state, the inline valve 24 is closed and the second pump 80 continues to run, holding the vacuum ballast chamber 85 under vacuum while, for example, the vacuum chamber 20 is vented to the atmosphere to allow for specimen removal, replacement, etc.

As is illustrated in FIG. 7, the evacuation system may further comprise a bypass valve 26. The bypass valve 26 is configured to permit evacuation of the vacuum chamber 20 solely by the first pump 70 when the bypass valve 26 is in a bypass state. In the open state, the bypass valve 26 permits evacuation of the vacuum chamber 20 by the first and second pumps 70, 80. In this manner, the vacuum chamber 20 can be differentially pumped through the first pump 70 while bypassing the second pump 80. The scheme of FIG. 7 effectively reduces the initial load on the second pump 80 during start-up and cuts a significant amount of time out of the usual vacuum chamber pump down cycle.

The treatment system 10 may further comprise a controller 90 programmed to affect a first transition of the evacuation system from an idle state to a cleaning cycle and a second transition from the cleaning cycle to the idle state. More specifically, the idle state can be characterized by operation of the first and second pumps 70, 80 in an active state, operation of the bypass valve 26 in the bypass state, placing the first pump 70 in communication with the vacuum chamber 20, and operation of the inline valve 24 in the closed state, isolating the second pump 80 from the vacuum chamber 20. The cleaning cycle can be characterized by operation of the first and second pumps 70, 80 in the active state, operation of the bypass valve 26 in the open state, and operation of the inline valve 26 in an open state, permitting evacuation of the vacuum chamber 20 by the first and second pumps 70, 80.

As is illustrated in FIGS. 4-7, the vacuum chamber 20 can be provided with an optically transparent window 28 to permit observation of a color of the plasma discharge. The plasma discharge treatment can be terminated when the color of the plasma indicates that a substantial portion of hydrocarbon contaminants have been removed from the surface of the specimen. Alternatively, or additionally, the treatment system can be provided with a residual gas analyzer 95 coupled to the vacuum chamber 20. The plasma discharge treatment can be terminated when gas analysis data of the process gas indicates that a substantial portion of hydrocarbon contaminants have been removed from the surface of the specimen. For example, the residual gas analyzer 95 can be configured to monitor a level of carbon in the process gas.

Mass flow controllers (not shown) may be provided to control the rate at which the process gases are introduced into the vacuum chamber 20. Typically, a gas duct will connect the mass flow controller to the associated source of process gas. It is noted that the respective ducts extending from the process gas sources to the chamber 20 will not be evacuated if the chamber 20 is evacuated with the mass flow controllers closed. Accordingly, care should be taken to open the mass flow controllers and evacuate the duct between the mass flow controller and the associated source prior to opening the source valve. A reading from the mass flow controller can be used to monitor the evacuation of the duct and determine when evacuation of the duct is complete.

It is noted that terms like “preferably,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention.

For the purposes of describing and defining the present invention it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. A specimen surface treatment system comprising a vacuum chamber, a plasma chamber, a specimen holder port, and a specimen shield, wherein:
said plasma chamber comprises an RF antenna positioned within said vacuum chamber so as to give rise to a capacitively coupled glow discharge plasma in a process gas contained within said vacuum chamber;
said specimen holder port is configured to define a specimen position within said capacitively coupled glow discharge and to permit introduction of a specimen into said vacuum chamber and removal of a specimen from said vacuum chamber; and
said specimen shield is positioned within said vacuum chamber so as to define a preferred grounding path between said RF antenna and said specimen shield for ions generated in said plasma, wherein said grounding path is preferred relative to a grounding path defined between said RF antenna and said specimen position.

2. A specimen surface treatment system as claimed in claim 1 wherein said RF antenna, said specimen shield, and said specimen position are defined within said vacuum chamber such that at least a substantial portion of said specimen shield is between said RF antenna and a specimen holder in said specimen position.

3. A specimen surface treatment system as claimed in claim 1 wherein:
said specimen shield defines a plasma port along an indirect plasma path between said RF antenna and said specimen position; and
said indirect plasma path incorporates a change in direction approximating an angle of at least about 90 degrees.

4. A specimen surface treatment system as claimed in claim 1 wherein:
said plasma chamber defines a portion of said vacuum chamber and comprises a conductive portion; and
a capacitive coating is formed over said conductive portion of said plasma chamber.

5. A specimen surface treatment system as claimed in claim 4 wherein said portions of said plasma chamber over which said capacitive coating is formed comprise portions of enhanced roughness.

6. A specimen surface treatment system as claimed in claim 1 wherein:
said plasma chamber defines a portion of said vacuum chamber and a conductive portion surrounding at least a portion of said RF antenna; and
a capacitive coating is formed over said conductive portion.

7. A specimen surface treatment system as claimed in claim 6 wherein said conductive portion and said RF antenna define substantially concentric cylindrical cross sections and said capacitive coating is distributed about an interior circumference of said conductive portion.

8. A specimen surface treatment system as claimed in claim 6 wherein said capacitive coating comprises a carbonaceous material.

9. A specimen surface treatment system as claimed in claim 1 wherein said RF antenna comprises a hollow cathode glow discharge antenna.

10. A specimen surface treatment system as claimed in claim 1 wherein said plasma chamber is configured to operate at between about 10 W and about 100 W.

11. A specimen surface treatment system as claimed in claim 1 wherein said RF antenna, said specimen shield, and said specimen position are defined within said vacuum chamber such that a plasma potential in a shielded region between said shield and a specimen holder in said specimen position is less than about 30 V above a floating potential of said specimen holder.

12. A specimen surface treatment system as claimed in claim 11 wherein said plasma potential is about 20V above a floating potential of said specimen holder.

13. A specimen surface treatment system as claimed in claim 1 wherein said RF antenna and said specimen shield are positioned within said vacuum chamber such that a potential difference between a plasma potential in a shielded region and a potential of said specimen shield is greater than a potential difference between said plasma potential and a floating potential of a specimen in said specimen position.

14. A specimen surface treatment system as claimed in claim 13 wherein said plasma potential is about 20V above a floating potential of said specimen shield.

15. A specimen surface treatment system as claimed in claim 1 wherein said RF antenna, said specimen shield, and a specimen holder in said specimen position are defined within said vacuum chamber such that a plasma potential in a shielded region between said shield and said specimen holder is less than about 30 V above a floating potential of said specimen holder and said specimen shield.

16. A specimen surface treatment system as claimed in claim 15 wherein said RF antenna, said specimen shield, and said specimen holder are positioned within said vacuum chamber such that at least a substantial portion of said specimen shield is between said RF antenna and said specimen holder.

17. A specimen surface treatment system as claimed in claim 1 wherein said treatment system further comprises an evacuation system configured to evacuate said vacuum chamber and maintain said vacuum chamber below about 600 mTorr (80 Pa).

18. A specimen surface treatment system as claimed in claim 1 wherein said treatment system further comprises an evacuation system configured to evacuate said vacuum chamber and maintain said vacuum chamber between about 300 mTorr (40 Pa) and about 600 mTorr (80 Pa).

19. A specimen surface treatment system as claimed in claim 1 wherein:
said treatment system further comprises an evacuation system coupled to said vacuum chamber via an evacuation port; and
a vacuum line extending from said evacuation port comprises an inline valve configured to isolate said evacuation system from said vacuum chamber when said inline valve is in a closed state.

20. A specimen surface treatment system as claimed in claim 19 wherein said evacuation system further comprises a vacuum ballast chamber positioned between said inline valve and a pumping component of said evacuation system.

21. A specimen surface treatment system as claimed in claim 1 wherein:
said treatment system further comprises an evacuation system configured to evacuate said vacuum chamber;
said evacuation system comprises a first pump configured to evacuate said vacuum chamber from atmospheric pressure to a reduced pressure and a second pump configured to evacuate said vacuum chamber from said reduced pressure to a further reduced pressure; and
said evacuation system further comprises a bypass valve configured to permit evacuation of said vacuum chamber by said first pump when said bypass valve is in a bypass state.

22. A specimen surface treatment system as claimed in claim 21 wherein said bypass valve is further configured to permit evacuation of said vacuum chamber by said first and second pumps when said bypass valve is in an open state.

23. A specimen surface treatment system as claimed in claim 21 wherein:
said treatment system further comprises a controller programmed to affect a first transition of said evacuation system from an idle state to a cleaning cycle and a second transition from said cleaning cycle to said idle state;
said idle state is characterized by operation of said first and second pumps in an active state, operation of said bypass valve in said bypass state so as to place said first pump in communication with said vacuum chamber, and operation of said inline valve in said closed state so as to isolate said second pump from said vacuum chamber; and
said cleaning cycle is characterized by operation of said first and second pumps in said active state, operation of said bypass valve in said open state so as to permit evacuation of said vacuum chamber by said first and second pumps, and operation of said inline valve in an open state.

24. A specimen surface treatment system as claimed in claim 1 wherein said vacuum chamber is provided with an optically transparent window configured to permit observation of a color of said plasma discharge and termination of said plasma discharge generation when said color observation is indicative of removal of a substantial portion of hydrocarbon contaminants from said surface of said specimen.

25. A specimen surface treatment system as claimed in claim 1 wherein said treatment system comprises a residual gas analyzer coupled to said vacuum chamber such that said generation of said plasma discharge may be terminated when gas analysis data of said process gas is indicative of removal of a substantial portion of hydrocarbon contaminants from said surface of said specimen.

26. A specimen surface treatment system as claimed in claim 25 wherein said residual gas analyzer is configured to monitor a level of carbon in said process gas.

27. A specimen surface treatment system comprising a vacuum chamber, a plasma chamber, and first and second specimen holder ports defined in said vacuum chamber, wherein:
said plasma chamber comprises an RF antenna positioned within said vacuum chamber so as to give rise to a capacitively coupled glow discharge plasma in a process gas contained within said vacuum chamber;
said first specimen holder port is configured to define a first specimen position within said capacitively coupled glow discharge and to permit introduction of a specimen into said vacuum chamber and removal of said specimen from said vacuum chamber; and
said second specimen holder port is configured to define a second specimen position within said capacitively coupled glow discharge and to permit introduction of a specimen into said vacuum chamber and removal of said specimen from said vacuum chamber; and
said first and second specimen positions defined by said first and second specimen holder ports lie in the same or substantially equivalent glow discharge plasma zones within said vacuum chamber.

28. A specimen surface treatment system as claimed in claim 37 wherein said first and second specimen holder ports comprise respective adapters configured to accommodate different types of specimen holder designs.

29. A method of removing hydrocarbon contaminants from a surface of a specimen, said method comprising:
positioning said specimen within a vacuum chamber of a surface treatment system, said surface treatment system comprising a plasma chamber, a specimen holder, an evacuation system, and a process gas supply;
generating a glow discharge plasma within said vacuum chamber by evacuating said chamber, activating said plasma chamber, and introducing said process gas into said vacuum chamber; and
removing said specimen from said vacuum chamber following contaminant removal by isolating at least a portion of said evacuation system from said vacuum chamber in a manner sufficient to hinder transfer of hydrocarbon contaminants from said evacuation system to said vacuum chamber as said vacuum chamber is vented to atmospheric pressure.

30. A method of removing hydrocarbon contaminants as claimed in claim 29 wherein said evacuation system is isolated from said vacuum chamber by closing an inline valve between said evacuation system and said vacuum chamber.

31. A method of removing hydrocarbon contaminants as claimed in claim 29 wherein said evacuation system is maintained in an active state after said chamber is vented to atmospheric pressure.

32. A method of removing hydrocarbon contaminants as claimed in claim 31 wherein a vacuum ballast chamber positioned between said inline valve and a pumping component of said evacuation system is maintained under vacuum by said pumping component following removal of said specimen from said vacuum chamber.

33. A method of removing hydrocarbon contaminants as claimed in claim 29 wherein said evacuation system comprises a first pump configured to evacuate said vacuum chamber from atmospheric pressure to a reduced pressure and a second pump configured to evacuate said vacuum chamber from said reduced pressure to a further reduced pressure and said method comprises isolating said second pump from said vacuum chamber while permitting said first pump to evacuate said vacuum chamber to said reduced pressure.

34. A method of removing hydrocarbon contaminants as claimed in claim 33 wherein said second pump is maintained in an active state while said first pump evacuates said vacuum chamber.

35. A method of removing hydrocarbon contaminants as claimed in claim 33 wherein said second pump maintains a vacuum ballast chamber under vacuum while said first pump evacuates said vacuum chamber.

36. A method of removing hydrocarbon contaminants as claimed in claim 33 wherein said second pump is placed into communication with said vacuum chamber when said vacuum chamber reaches said reduced pressure.

37. A method of removing contaminants from a surface of a specimen, said method comprising:
positioning said specimen within a vacuum chamber of a surface treatment system, said surface treatment system comprising a plasma chamber, a specimen holder, an evacuation system, and a process gas supply;
generating a glow discharge plasma within said vacuum chamber by evacuating said chamber, activating said plasma chamber, and introducing said process gas into said vacuum chamber; and
removing said specimen from said vacuum chamber following contaminant removal by introducing a gas into said vacuum chamber in a manner sufficient to hinder backstreaming of hydrocarbon contaminants from said evacuation system to said vacuum chamber as said vacuum chamber is vented to atmospheric pressure.
